(19) United States
(12) Patent Application Publication
(10) Pub. No.: US 2007/0235820 A1
(43) Pub. Date: Oct. 11, 2007

(54) Manufacturing method of semiconductor device and semiconductor device

(75) Inventor: Yasuo Ohtsuki, Kurokawa-gun (JP)

Correspondence Address: BIRCH STEWART KOLASCH & BIRCH, PO BOX 747, FALLS CHURCH, VA, 22040-0747, US

(73) Assignee: FUJIFILM Corporation

(21) Appl. No.: 11/783,029

(22) Filed: Apr. 5, 2007

(30) Foreign Application Priority Data
Apr. 6, 2006 (JP) P.2006-105154

(51) Int. Cl. H01L 29/94; H01L 29/76; H01L 31/00

(52) U.S. Cl. 257/410

(57) ABSTRACT

A method for manufacturing a semiconductor device including a semiconductor substrate, and a first electrode and a second electrode insulated from each other and formed in an upper side of the semiconductor substrate, wherein the method includes: forming the first electrode whose surface excluding its bottom surface is covered by a nitride layer on a gate dielectric layer formed on the semiconductor substrate; after the forming of the first electrode whose surface excluding its bottom surface is covered by a nitride layer, forming a conductive layer on the semiconductor substrate; and subjecting the conductive layer to patterning to form the second electrode.

### FIELD OF THE INVENTION

The present invention relates to a manufacturing method of a semiconductor device in which a first electrode and a second electrode insulated from each other are formed in an upper side of a semiconductor substrate.

### BACKGROUND OF THE INVENTION

A solid-state imaging device of a CCD type which is used in an area sensor or the like has a charge transfer electrode for the purpose of transferring a signal charge from a photoelectric conversion part. Plural charge transfer electrodes are disposed adjacent to each other on a charge transfer path formed in a semiconductor substrate and driven successively.

In a solid-state imaging device, an increase of the number of imaging pixels proceeds. However, following the increase of the number of pixels, high-speed transfer of a signal charge, namely drive of a charge transfer electrode by a high-speed pulse is necessary, and therefore, realization of a low resistivity of a charge transfer electrode is demanded. As a method of realizing a low resistivity, it is proposed to configure the charge transfer electrode so as to have a two-layer structure of a silicon based conductive material such as polycrystalline silicon and a metallic silicide.

On the other hand, a region of a photoelectric conversion part tends to become narrow due to the increase of the number of imaging pixels. In order to condense a large amount of light in a narrow region, it is important to make a height of the periphery of the photoelectric conversion part such as a charge transfer electrode forming part lower against the surface of the photoelectric conversion part, thereby reducing eclipse (blocking) of light by the electrode. For that reason, there is proposed a charge transfer electrode of a so-called single-layer structure in which charge transfer electrodes are disposed without being superimposed on each other (see, for example, JP-A-2004-342912). When the charge transfer electrode is configured to have a single-layer structure, a difference in level is reduced, and coating properties of a light-shielding layer on the transfer electrode part are improved, and therefore, such is more effective.

In such a charge transfer electrode of a two-layer structure or a single-layer structure, there is generally employed a measure in which after forming an electrode as a first layer by using polysilicon or the like, this electrode as a first layer is thermally oxidized to form a dielectric layer in the periphery of the electrode as a first layer and this dielectric layer is made to work as an interelectrode dielectric layer for insulating the electrode as a first layer and an electrode as a second layer from each other.

### SUMMARY OF THE INVENTION

However, when the electrode as a first layer is thermally oxidized to form an interelectrode dielectric layer, there is involved a problem that the electrode as a first layer becomes thin. In particular, in the case where a polycrystalline layer is used as a conductive layer constituting the electrode as a first layer, since an oxidization rate on a grain boundary of the polycrystalline layer is faster than that in other portions, the electrode as a first layer does not become uniformly thin but becomes thin locally on the grain boundary. As a result, interelectrode leakage is generated or breaking of a wire is generated, whereby the reliability is lowered.

Under the foregoing circumstances, the invention has been made, and an object thereof is to provide a manufacture method of a semiconductor device having two kinds of electrodes insulated from each other by a dielectric layer and capable of improving its reliability.

The manufacturing method of a semiconductor device according to the invention is a manufacturing method of a semiconductor device having a semiconductor substrate and a first electrode and a second electrode insulated from each other and formed in an upper side of the semiconductor substrate, wherein a forming step of the first electrode and the second electrode includes a first electrode forming step of forming the first electrode whose surface excluding its bottom surface is covered by a nitride layer on a gate dielectric layer formed on the semiconductor substrate; a step of, after the formation of the first electrode whose surface excluding its bottom surface is covered by a nitride layer, forming a conductive layer on the semiconductor substrate; and a step of subjecting the conductive layer to patterning to form the second electrode.

In the manufacturing method of a semiconductor device according to the invention, the first electrode forming step includes a step of forming a conductive layer which is a material of the first electrode on the gate dielectric layer; a step of forming a first nitride layer on the conductive layer which is a material of the first electrode; a step of subjecting the conductive layer which is a material of the first electrode and the first nitride layer to patterning to form the first electrode in which the first nitride layer retains on an upper surface thereof; and a step of, after the patterning, forming a second nitride layer on at least a side wall of the first electrode.

In the manufacturing method of a semiconductor device according to the invention, the first electrode forming step includes a step of forming the first electrode on the gate dielectric layer and a step of, after the formation of the first electrode, forming the nitride layer on the semiconductor substrate.

In the manufacturing method of a semiconductor device according to the invention, the semiconductor device is a solid-state imaging device of a CCD type; and the first electrode and the second electrode are each a charge transfer electrode to be contained in the solid-state imaging device of a CCD type.

The semiconductor device according to the invention is a semiconductor device having a semiconductor substrate and a first electrode and a second electrode insulated from each other by an interelectrode dielectric layer and formed in an upper side of the semiconductor substrate, which is provided with a nitride layer which functions as the interelectrode dielectric layer and which covers a surface of the first electrode excluding its bottom surface.

In the semiconductor device according to the invention, the semiconductor device is a solid-state imaging device of a CCD type; and the first electrode and the second electrode are each a charge transfer electrode to be contained in the solid-state imaging device of a CCD type.

According to the invention, it is possible to provide a manufacture method of a semiconductor device having two kinds of electrodes insulated from each other by a dielectric layer and capable of improving its reliability.

### BRIEF DESCRIPTION OF THE DRAWINGS

FIGS 1A to 1D are each a cross-sectional schematic view to show a forming step of a charge transfer electrode to be contained in a solid-state imaging device of a CCD type for the purpose of explaining a first embodiment of the invention.

FIGS. 2E to 2G are each a cross-sectional schematic view to show a forming step of a charge transfer electrode to be contained in a solid-state imaging device of a CCD type for the purpose of explaining a first embodiment of the invention.

FIGS. 3A to 3E are each a cross-sectional schematic view to show a forming step of a charge transfer electrode to be contained in a solid-state imaging device of a CCD type for the purpose of explaining a second embodiment of the invention.

FIGS. 4F to 4I are each a cross-sectional schematic view to show a forming step of a charge transfer electrode to be contained in a solid-state imaging device of a CCD type for the purpose of explaining a second embodiment of the invention.

FIGS. 5A to 5D are each a cross-sectional schematic view to show a forming step of a charge transfer electrode to be contained in a solid-state imaging device of a CCD type for the purpose of explaining a third embodiment of the invention.

FIGS. 6E to 6H are each a cross-sectional schematic view to show a forming step of a charge transfer electrode to be contained in a solid-state imaging device of a CCD type for the purpose of explaining a third embodiment of the invention.

### DESCRIPTION OF REFERENCE NUMERALS AND SIGNS

1: Silicon substrate

2, 2′: Gate dielectric layer

2a, 2c, 12: Silicon oxide layer

2b: Silicon nitride layer

5: Stopper layer

4, 6, 9, 11: Nitride layer

3, 8, 10, 13: Conductive layer

### DETAILED DESCRIPTION OF THE INVENTION

Embodiments of the invention are hereunder described with reference to the accompanying drawings.

### First Embodiment

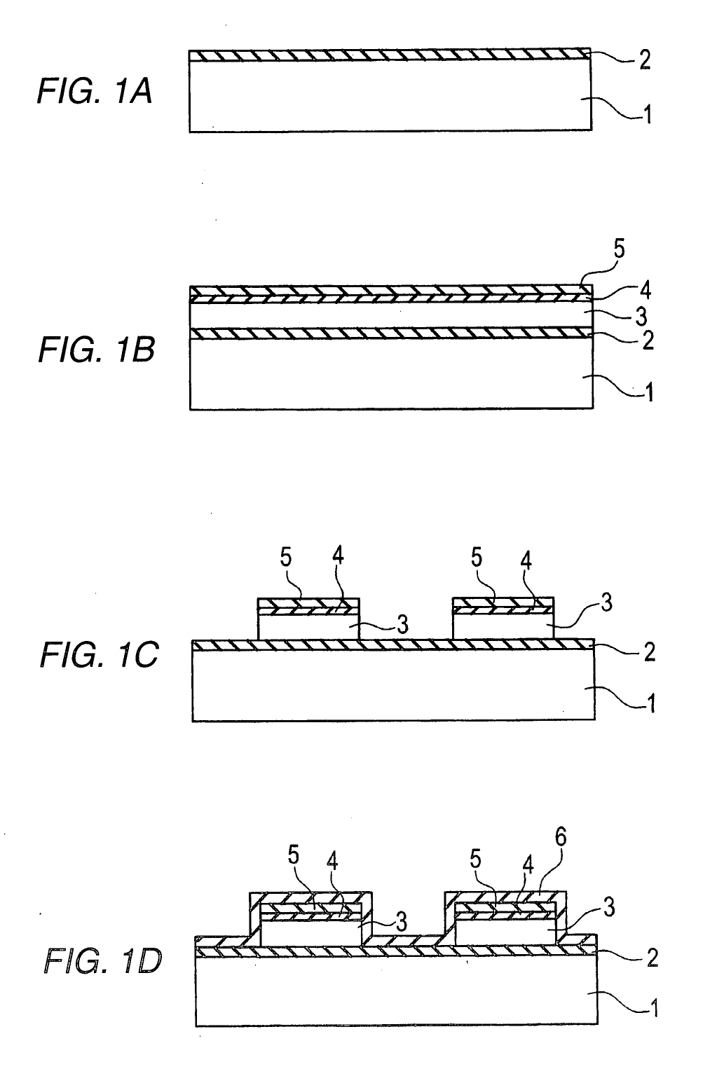

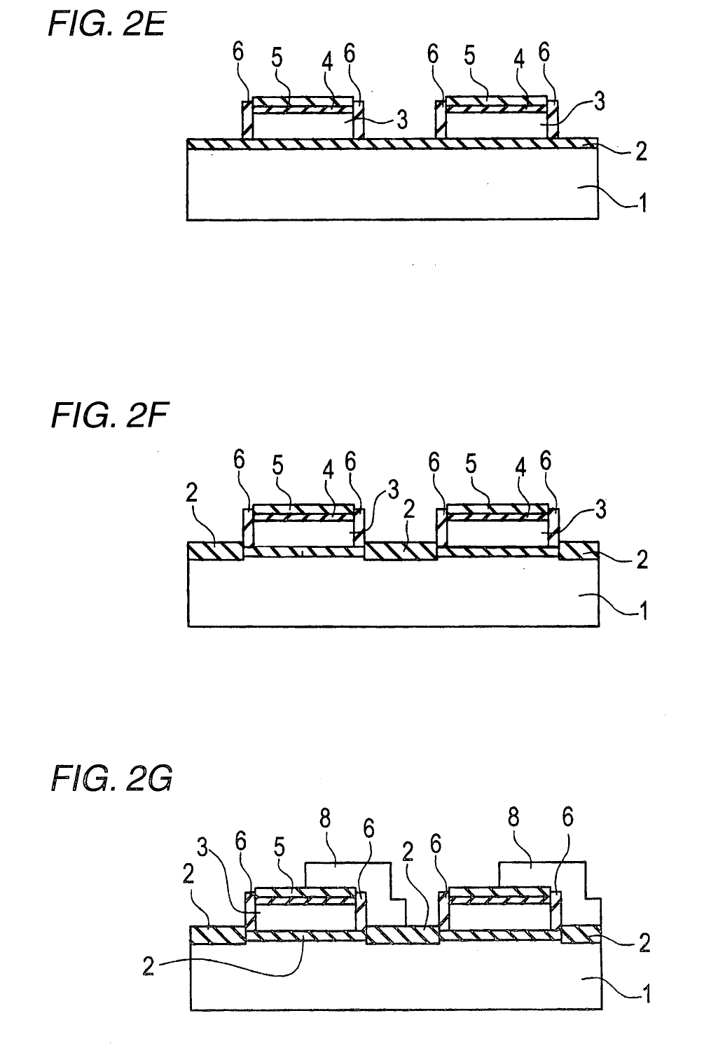

FIGS. 1A to 1D and FIGS. 2E to 2G are each a cross-sectional schematic view to show a forming step of a charge transfer electrode to be contained in a solid-state imaging device of a CCD type for the purpose of explaining a first embodiment of the invention. In this solid-state imaging device of a CCD type, a manufacturing method of portions other than the charge transfer electrode is the same as known ones.

First of all, a gate dielectric layer 2 made of, for example, silicon oxide (SiO₂) and having a thickness of 1,000 angstroms is formed on a silicon substrate 1 (see FIG. 1A). Next, a conductive layer 3 made of, for example, polysilicon and having a thickness of 4,000 angstroms is formed on the gate dielectric layer 2; a nitride 4 (corresponding to the first nitride layer) made of, for example, silicon nitride (SiN) and having a thickness of 1,000 angstroms is formed on the conductive layer 3; and a stopper layer 5 made of, for example, silicon oxide (SiO₂) and having a thickness of 1,000 angstroms is formed on the nitride layer 4 by means of CVD (see FIG. 1B). This stopper layer 5 plays a role as a stopper in a later etching step.

Next, after forming a mask on the stopper layer 5 by means of photolithography, reactive ion etching (RIE) is carried out to achieve patterning of the conductive layer 3, the nitride layer 4 and the stopper layer 5 (see FIG. 1C). A pattern of the conductive layer 3 formed by this patterning becomes an electrode as a first layer of charge transfer electrodes (corresponding to the first electrode).

Next, a nitride layer 6 made of, for example, silicon nitride and having a thickness of 1,000 angstroms (corresponding to the second nitride layer) is formed on the silicon substrate 1 (see FIG. 1D).

Next, RIE is carried out while making the stopper layer 5 work as s topper, thereby removing the nitride layer 6 while retaining the nitride layer 6 in a side wall of the conductive layer 3 having been subjected to patterning (see FIG. 2E). In this way, the conductive layer 3 having been subjected to patterning becomes in a state that a surface thereof excluding its bottom surface is covered by the nitride layer 4 and the nitride layer 6.

In etching the nitride layer 6 by means of RIE, there may be a possibility that a part of the gate dielectric layer 2 is also etched. Though it is necessary to form an electrode as a second layer of charge transfer electrodes on the gate dielectric layer 2, there may be the case where the thickness of the gate dielectric layer 2 is not sufficient by this etching. In that case, the thickness of the gate dielectric layer 2 is increased by means of an oxidation treatment or CVD (see FIG. 2F). Incidentally, when the thickness of the gate dielectric layer 2 is sufficient, the step of FIG. 2F can be omitted. In FIG. 2F, the case where the thickness of the gate dielectric layer 2 is increased is illustrated.

Next, a conductive layer 8 made of, for example, polysilicon and having a thickness of 4,000 angstroms is formed on the silicon substrate 1; and after forming a mask on this conductive layer 8 by means of photolithography, the conductive layer 8 is subjected to patterning by means of RIE (see FIG. 2G). The conductive layer 8 having been subjected to patterning becomes an electrode as a second layer of charge transfer electrodes (corresponding to the second electrode), whereby a charge transfer electrode having a two-layer structure is formed.

According to the forming step of such a charge transfer electrode, since the surface of the electrode as a first layer excluding its bottom surface is covered by a nitride layer and the electrode as a second layer is formed while making this nitride layer work as an interelectrode dielectric layer, it is possible to form the electrode as a first layer and the electrode as a second layer insulated from each other without oxidizing the electrode as a first layer. Accordingly, it is possible to prevent the matter that the electrode as a first layer becomes thin and to improve the reliability of a solid-state imaging device. Also, according to this forming step, since the periphery of the electrode as a first layer is covered by a nitride layer, even in the case where after forming the electrode as a first layer, an oxidation treatment or the like is carried out, it is possible to prevent the matter that the electrode as a first layer becomes thin.

Incidentally, since an object of the present method is to form the electrode as a second layer by covering the surface of the conductive layer 3 having been subjected to patterning excluding its bottom surface, the step of FIG. 2E may be omitted. In that case, the formation of the stopper layer 5 is not necessary. Also, in that case, after forming the charge transfer electrode, it is necessary to form a hole for hydrogen annealing in a part of the nitride layer 6.

### Second Embodiment

The formation step of a charge transfer electrode as explained in the present embodiment is a forming step of the case where the gate dielectric layer of the solid-state imaging device as explained in the first embodiment is of an ONO structure but not a single-layer structure.

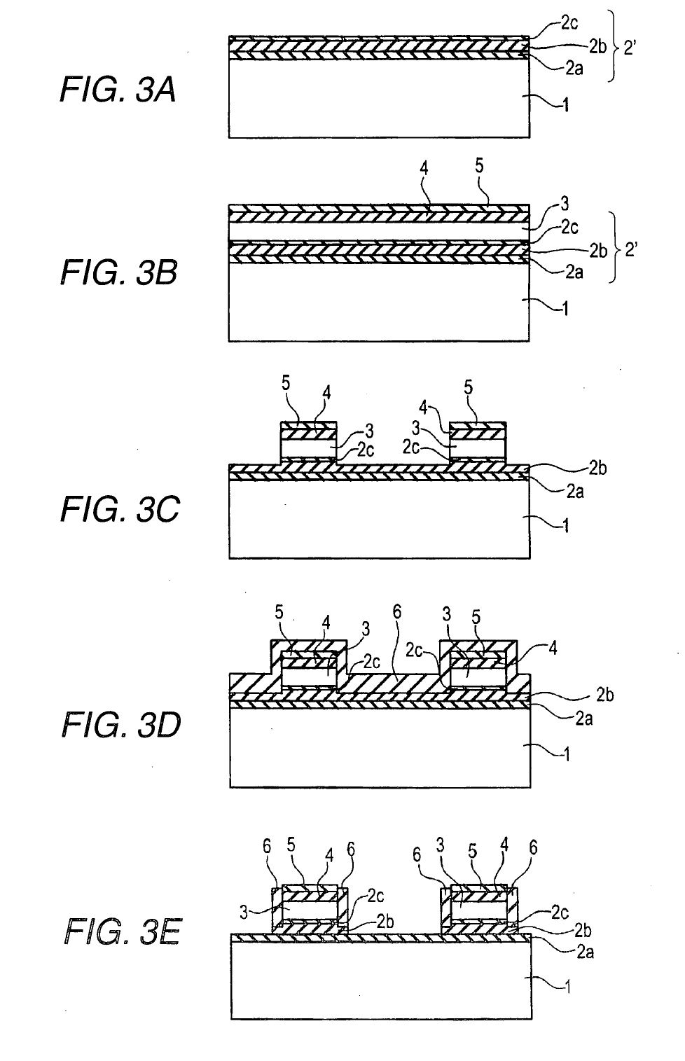

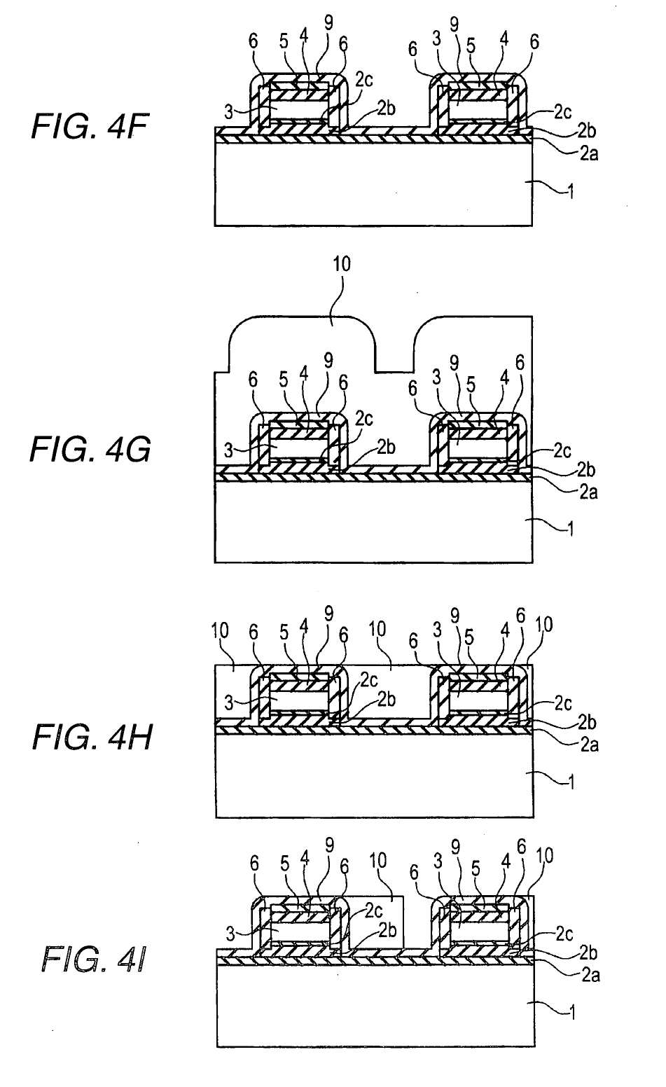

FIGS. 3A to 3E and FIGS. 4F to 4I are each a cross-sectional schematic view to show a forming step of a charge transfer electrode to be contained in a solid-state imaging device of a CCD type for the purpose of explaining a second embodiment of the invention. In FIGS. 3A to 3E and FIGS. 4F to 4I, the same configurations as those in FIGS. 1A to 1D and FIGS. 2E to 2G are given the same symbols. In this solid-state imaging device of a CCD type, the manufacturing methods of portions other than the charge transfer electrode are the same as known ones.

First of all, a silicon oxide layer 2a having a thickness of 250 angstroms, a silicon nitride layer 2b having a thickness of 500 angstroms and a silicon oxide layer 2c having a thickness of 80 angstroms are stacked successively on a silicon substrate 1, thereby forming a gate dielectric layer 2′ having an ONO structure (see FIG. 3A).

Next, a conductive layer 3 made of, for example, polysilicon and having a thickness of 5,000 angstroms is formed on the gate dielectric layer 2′; a nitride layer 4 made of, for example, silicon nitride (SiN) and having a thickness of 1,000 angstroms is formed on the conductive layer 3; and s stopper layer 5 made of, for example, silicon oxide (SiO₂) and having a thickness of 500 angstroms is formed on the nitride layer 4 by means of CVD (see FIG. 3B). This stopper layer 5 plays a role as a stopper in a later etching step.

Next, after forming a mask on the stopper layer 5 by means of photolithography, RIE is carried out to achieve patterning of the conductive layer 3, the nitride layer 4 and the stopper layer 5 (see FIG. 3C). A pattern of the conductive layer 3 formed by this patterning becomes an electrode as a first layer of charge transfer electrodes (corresponding to the first electrode). The silicon oxide layer 2c of the gate dielectric layer 2′ and a part of the silicon nitride layer 2b are also etched by this RIE.

Next, a nitride layer 6 made of, for example, silicon nitride and having a thickness of 500 angstroms is formed on the silicon substrate 1 (see FIG. 3D).

Next, RIE is carried out while making the stopper layer 5 work as a topper, thereby retaining the nitride layer 6 in a side wall of the conductive layer 3 having been subjected to patterning and removing the other nitride layer 6 and a part of the silicon nitride layer 2b (see FIG. 3E). In this way, the conductive layer 3 having been subjected to patterning becomes in a state that a surface thereof excluding its bottom surface is covered by the nitride layer 4 and the nitride layer 6.

In the step of FIG. 3E, since a part of the silicon nitride layer 2b is also removed, for the purpose of making up a shortage of this gate dielectric layer 2′, a silicon nitride layer 9 having a thickness of 500 angstroms is formed by means of oxidation or CVD (see FIG. 4F). FIG. 4F illustrates an example in which the silicon nitride layer 9 is formed by means of LP-CVD. Incidentally, in the step of FIG. 3E, if RIE is carried out such that the part of the silicon nitride layer 2b is not removed, the step of FIG. 4F is not necessary.

Next, a conductive layer 10 made of, for example, polysilicon and having a thickness of 6,000 angstroms is formed on the silicon substrate 1 (see FIG. 4G). Next, the conductive layer 10 is flattened by means of CMP while making the silicon nitride layer 9 work as a stopper (see FIG. 4H).

Next, after forming a mask on the flattened conductive layer 10 by means of photolithography, the conductive layer 10 is subjected to patterning by means of RIE (see FIG. 4I). The conductive layer 10 having been subjected to patterning becomes an electrode as a second layer of charge transfer electrodes (corresponding to the second electrode), whereby a charge transfer electrode having a single-layer structure is formed. In the case where the silicon nitride layer 9 is formed in FIG. 4F or in the case where the silicon nitride layer 2b is not removed by etching in FIG. 3E, after forming the charge transfer electrode having a single-layer structure, it is necessary to form a hole for hydrogen annealing in a part of the nitride layer 9 or a part of the silicon nitride layer 2b.

According to the forming step of such a charge transfer electrode, since the surface of the electrode as a first layer excluding its bottom surface is covered by a nitride layer and the electrode as a second layer is formed via this nitride layer, it is possible to form the electrode as a first layer and the electrode as a second layer insulated from each other without oxidizing the electrode as a first layer. Accordingly, it is possible to prevent the matter that the electrode as a first layer becomes thin and to improve the reliability of a solid-state imaging device. Also, according to this forming step, since the periphery of the electrode as a first layer is covered by a nitride layer, even in the case where after forming the electrode as a first layer, an oxidation treatment or the like is carried out, it is possible to prevent the matter that the electrode as a first layer becomes thin.

### Third Embodiment

The formation step of a charge transfer electrode as explained in the present embodiment is a forming step of the case where the gate dielectric layer of the solid-state imaging device as explained in the first embodiment is of an ONO structure but not a single-layer structure.

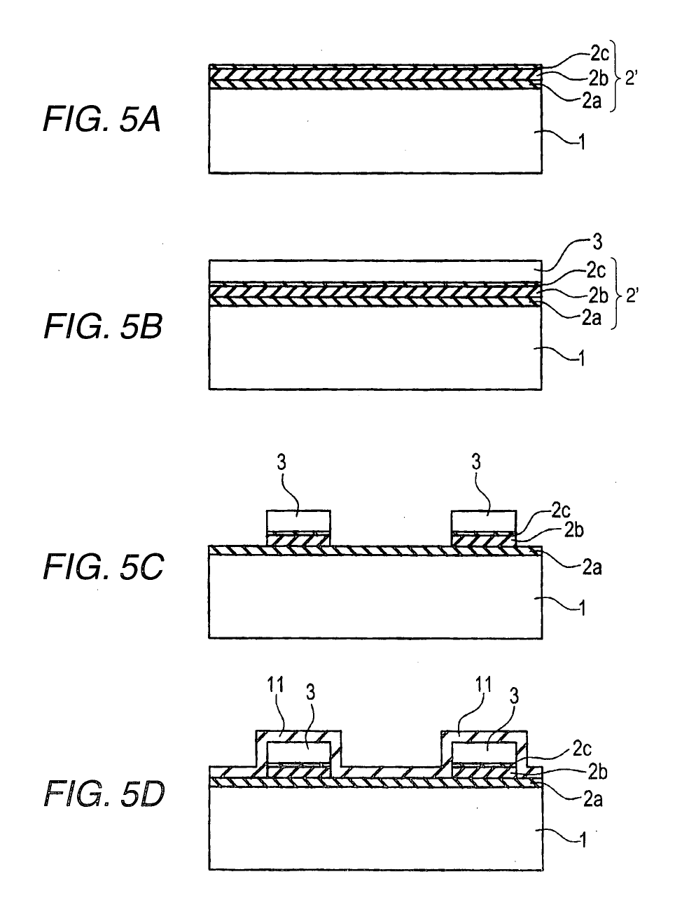

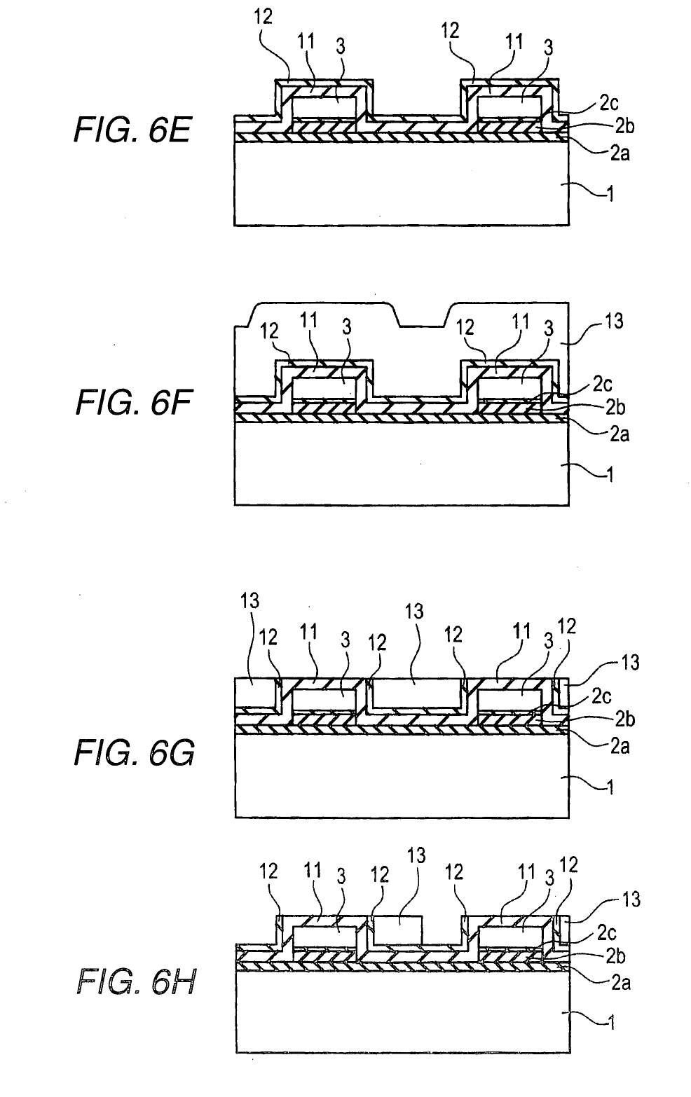

FIGS. 5A to 5D and FIGS. 6E to 6H are each a cross-sectional schematic view to show a forming step of a charge transfer electrode to be contained in a solid-state imaging device of a CCD type for the purpose of explaining a third embodiment of the invention. In FIGS. 5A to 5D and FIGS. 6E to 6H, the same configurations as those in FIGS. 3A to 3E and FIGS. 4F to 4I are given the same symbols. In this solid-state imaging device of a CCD type, the manufacturing methods of portions other than the charge transfer electrode are the same as known ones.

First of all, a gate dielectric layer 2′ having an ONO structure is formed on a silicon substrate 1 (see FIG. 5A). Next, a conductive layer 3 made of, for example, polysilicon and having a thickness of 5,000 angstroms is formed on the gate dielectric layer 2′ (see FIG. 5B)

Next, after forming a mask on the conductive layer 3 by means of photolithography, RIE is carried out to achieve patterning of the conductive layer 3, a silicon oxide layer 2c and a silicon nitride layer 2b (see FIG. 5C). A pattern of the conductive layer 3 formed by this patterning becomes an electrode as a first layer of charge transfer electrodes (corresponding to the first electrode).

Next, a nitride layer 11 made of, for example, silicon nitride and having a thickness of 500 angstroms is formed on the silicon substrate 1 (see FIG. 5D). In this way, the conductive layer 3 having been subjected to patterning becomes in a state that a surface thereof excluding its bottom surface is covered by the nitride layer 11. Next, for the purpose of making up a shortage of this gate dielectric layer 2′, a silicon oxide layer 12 is formed on the nitride layer 11 by a CVD method (see FIG. 6E). It is also possible to omit the formation of the silicon oxide layer 12.

Next, a conductive layer 13 made of, for example, polysilicon and having a thickness of 6,000 angstroms is formed on the silicon substrate 1 (see FIG. 6F). Next, the conductive layer 13 is flattened while making the silicon oxide layer 12 work as a stopper (see FIG. 6G)

Next, after forming a mask on the flattened conductive layer 13 by means of photolithography, the conductive layer 13 is subjected to patterning by means of RIE (see FIG. 6H). The conductive layer 13 having been subjected to patterning becomes an electrode as a second layer of charge transfer electrodes (corresponding to the second electrode), whereby a charge transfer electrode having a single-layer structure is formed. In the case of this formation method, after forming the charge transfer electrode having a single-layer structure, it is necessary to form a hole for hydrogen annealing in a part of the nitride layer 11.

According to the forming step of such a charge transfer electrode, since the surface of the electrode as a first layer excluding its bottom surface is covered by a nitride layer and the electrode as a second layer is formed via this nitride layer, it is possible to form the electrode as a first layer and the electrode as a second layer insulated from each other without oxidizing the electrode as a first layer. Accordingly, it is possible to prevent the matter that the electrode as a first layer becomes thin and to improve the reliability of a solid-state imaging device. Also, according to this forming step, since the periphery of the electrode as a first layer is covered by a nitride layer, even in the case where after forming the electrode as a first layer, an oxidation treatment or the like is carried out, it is possible to prevent the matter that the electrode as a first layer becomes thin.

Though the foregoing explanations have been made while referring to the forming step of a charge transfer electrode of a solid-state imaging device as an example, the foregoing method can be applied to a semiconductor device in which two kinds of electrodes insulated from each other by an interelectrode dielectric layer are formed on a semiconductor substrate (for example, CCD/CMOS embedded devices and EEPROM).

This application is based on Japanese Patent application JP 2006-105154, filed Apr. 6, 2006, the entire content of which is hereby incorporated by reference, the same as if set forth at length.

What is claimed is:

1. A method for manufacturing a semiconductor device including a semiconductor substrate, and a first electrode and a second electrode insulated from each other and formed in an upper side of the semiconductor substrate, wherein
the method comprises:
forming the first electrode whose surface excluding its bottom surface is covered by a nitride layer on a gate dielectric layer formed on the semiconductor substrate;
after the forming of the first electrode whose surface excluding its bottom surface is covered by a nitride layer, forming a conductive layer on the semiconductor substrate; and
subjecting the conductive layer to patterning to form the second electrode.

2. The method according to claim 1, wherein the forming of the first electrode comprises:
forming a conductive layer on the gate dielectric layer, in which at least a part of the conductive layer is to become the first electrode;
forming a first nitride layer on the conductive layer;
subjecting the conductive layer and the first nitride layer to patterning to form the first electrode in which at least a part of the first nitride layer remains on an upper surface of the first electrode; and
after the patterning, forming a second nitride layer on at least a side wall of the first electrode.

3. The method according to claim 1, comprises:
forming the first electrode on the gate dielectric layer; and
after the forming of the first electrode, forming the nitride layer on the semiconductor substrate.

4. The method according to claim 1, wherein
the semiconductor device is a solid-state imaging device of a CCD type; and
each of the first electrode and the second electrode are a charge transfer electrode to be contained in the solid-state imaging device of a CCD type.

5. The method according to claim 1, wherein the patterning to form the second electrode is conducted by a reactive ion etching.

6. The method according to claim 2, wherein the patterning to form the first electrode is conducted by a reactive ion etching.

7. A semiconductor device comprising a semiconductor substrate and a first electrode and a second electrode insulated from each other by an interelectrode dielectric layer and formed in an upper side of the semiconductor substrate, wherein the semiconductor device comprises a nitride layer which functions as the interelectrode dielectric layer and which covers a surface of the first electrode excluding its bottom surface.

8. The semiconductor device according to claim 7, wherein
the semiconductor device is a solid-state imaging device of a CCD type; and
each of the first electrode and the second electrode are a charge transfer electrode to be contained in the solid-state imaging device of a CCD type.
